(19) United States
(12) Patent Application Publication
(10) Pub. No.: US 2025/0225064 A1
(43) Pub. Date: Jul. 10, 2025

(54) TECHNIQUES FOR A UNIFIED SIMULATION INTERFACE

(71) Applicant: GM Cruise Holdings LLC, San Francisco, CA (US)

(72) Inventors: Jason Vrablik, Monroe, WA (US); Mahmood Miah, Seattle, WA (US); Desi Hsu, Foster City, CA (US); Harshitha Giri, Newark, CA (US); Tobias Marc Rene Thiel, San Francisco, CA (US)

(73) Assignee: GM Cruise Holdings LLC, San Francisco, CA (US)

(21) Appl. No.: 18/403,975

(22) Filed: Jan. 4, 2024

(51) Int. Cl. G06F 11/36

(52) U.S. Cl. CPC G06F 11/3698

(57) ABSTRACT

A unified simulation interface system is described and includes an interface module for receiving a simulation build graph, wherein the simulation build graph comprises a static portion and a dynamic portion, wherein the interface module generates application programming interface (API) payloads for execution nodes comprising the static portion of the simulation build graph; a simulation generator module for generating API payloads for execution nodes comprising the dynamic portion of the simulation build graph; and a remote build execution service for receiving the API payloads generated by the interface module and the simulation generator module, and scheduling execution of tasks in connection with the received API payloads on a compute cluster.

### TECHNICAL FIELD

The present disclosure relates generally to building and testing of software systems and, more specifically, to a unified simulation interface for use in autonomous vehicle (AV) infrastructure.

### BACKGROUND

### Introduction

An AV is a motorized vehicle that can navigate without a human driver. AVs include computers and control systems that perform driving and navigation tasks that are conventionally performed by a human driver. Such tasks require the collection and processing of large quantities of data using various sensors, including but not limited to, a camera sensor, a light detection and ranging (LIDAR) sensor, and a radio detection and ranging (RADAR) sensor, among others. The sensors collect data and measurements that the AV can use for operations such as navigation. The sensors can provide the data and measurements to an internal computing system of the AV, which can use the data and measurements to control a mechanical system of the AV, such as a vehicle propulsion system, a braking system, or a steering system. Typically, the sensors are mounted at fixed locations on the AVs.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1A illustrates an example system environment that can be used to facilitate AV dispatch and operations, according to some aspects of the disclosed technology;

FIGS. 1B-1D illustrate differences among a first example Remote Execution Application Programming Interface (REAPI) operation, a second example REAPI operation with large assets, and a third example REAPI operation with native object fetching, according to some aspects of the disclosed technology;

FIG. 2 illustrates a simplified block diagram of a unified simulation interface (USI) system, according to some aspects of the disclosed technology;

FIGS. 3 and 4 illustrate flowcharts of operations performed using a USI system, according to some aspects of the disclosed technology; and

FIG. 5 illustrates an example processor-based system with which some aspects of the disclosed technology can be implemented.

### DETAILED DESCRIPTION

### Overview

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

Given the numerous advantages of ride hail, rideshare, and delivery services (hereinafter collectively referred to as rideshare services) provided by AVs, it is anticipated that AV provision of such services will soon become the ubiquitous choice for various user transportation and delivery needs, including but not limited to school commutes, airport transfers, long distance road trips, and grocery and restaurant deliveries, to name a few.

As rideshare services provided by AVs have become more widely available, the complexity of AV automation has continued to increase. Automation of driving operations may be seen as adding a layer of cognitive intelligence to basic vehicle platforms. As perception and planning algorithms have become increasingly responsible for critical decisions made by AVs, software has emerged as a primary driver of AV innovation. It will be recognized that as the amount of software used to control AV operations grows, so does the need to deploy advanced software engineering methods and tools to manage and accommodate the complexity, size, and criticality of such software.

One area in which improvement in connection with software development and analysis may be needed is that of the command line interface (CLI) interaction that AV software developers (or AV engineers) must undergo to launch simulations. For example, in particular systems, there may be numerous CLI tools that may be used, depending on the simulation to be run. Each tool may implement each simulation input feature separately, leading to quadratic growth in implementations.

In accordance with features of embodiments described herein, a Bazel-integrated method is proposed by which users can leverage an existing simulation launch infrastructure. An easy-to-use command line interface (CLI) invocation provides for local-like execution run time look-and-feel while simultaneously providing the features of the current simulation launch structure. Additionally, through use of a Bazel build framework and Bazel REAPI as a front end to handle local dev loop requests, a uniform alternative may be provided that can properly reuse code and leverage existing computational framework, such as a simulation (sim) generator tool described herein. It will be recognized that although embodiments are described herein with reference to Bazel, embodiments may be advantageously employed in connection with other software tools for automating the building and testing of software.

Embodiments described herein employ a remote build execution (RBE) control plane to act as a switching layer between various simulation scheduling backends and to provide a unified API interface through which users can both build and test seamlessly. The RBE control plane is capable of understanding any Bazel command and translating it into a relevant compute cluster operation. In particular embodiments, this functionality is expanded to provide the ability to describe full compute cluster simulation targets as a Bazel invocation target, providing a natively understood target that will smartly run when code associated with the target changes. As a result, arbitrary compute cluster simulations may be scheduled using a native Bazel REAPI.

The following detailed description presents various descriptions of specific certain embodiments. However, the innovations described herein can be embodied in a multitude of different ways, for example, as defined and covered by the claims and/or select examples. In the following description, reference is made to the drawings, in which like reference numerals can indicate identical or functionally similar elements. It will be understood that elements illustrated in the drawings are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The following disclosure describes various illustrative embodiments and examples for implementing the features and functionality of the present disclosure. While particular components, arrangements, and/or features are described below in connection with various example embodiments, these are merely examples used to simplify the present disclosure and are not intended to be limiting. It will of course be appreciated that in the development of any actual embodiment, numerous implementation-specific decisions must be made to achieve the developer's specific goals, including compliance with system, business, and/or legal constraints, which may vary from one implementation to another. Moreover, it will be appreciated that, while such a development effort might be complex and time-consuming; it would nevertheless be a routine undertaking for those of ordinary skill in the art having the benefit of this disclosure.

In the drawings, a particular number and arrangement of structures and components are presented for illustrative purposes and any desired number or arrangement of such structures and components may be present in various embodiments. Further, the structures shown in the figures may take any suitable form or shape according to material properties, fabrication processes, and operating conditions. For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 110a-110e), such a collection may be referred to herein without the letters (e.g., as “110”).

In the Specification, reference may be made to the spatial relationships between various components and to the spatial orientation of various aspects of components as depicted in the attached drawings. However, as will be recognized by those skilled in the art after a complete reading of the present disclosure, the devices, components, members, apparatuses, etc. described herein may be positioned in any desired orientation. Thus, the use of terms such as “above”, “below”, “upper”, “lower”, “top”, “bottom”, or other similar terms to describe a spatial relationship between various components or to describe the spatial orientation of aspects of such components, should be understood to describe a relative relationship between the components or a spatial orientation of aspects of such components, respectively, as the components described herein may be oriented in any desired direction. When used to describe a range of dimensions or other characteristics (e.g., time, pressure, temperature, length, width, etc.) of an element, operations, and/or conditions, the phrase “between X and Y” represents a range that includes X and Y. The terms “substantially,” “close,” “approximately,” “near,” and “about,” generally refer to being within +/−20% of a target value (e.g., within +/−5 or 10% of a target value) based on the context of a particular value as described herein or as known in the art.

As described herein, one aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

Other features and advantages of the disclosure will be apparent from the following description and the claims.

### Example AV Management System

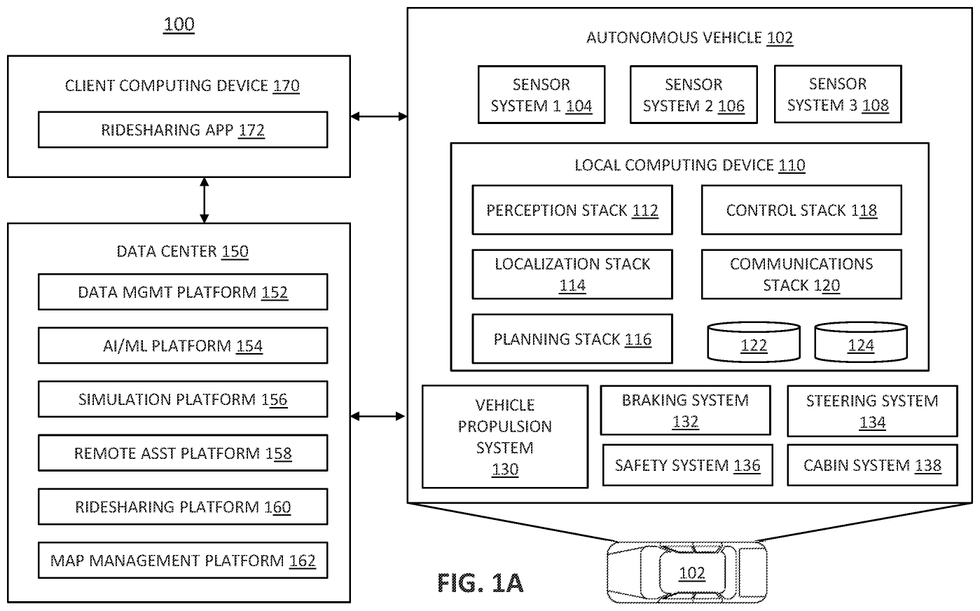

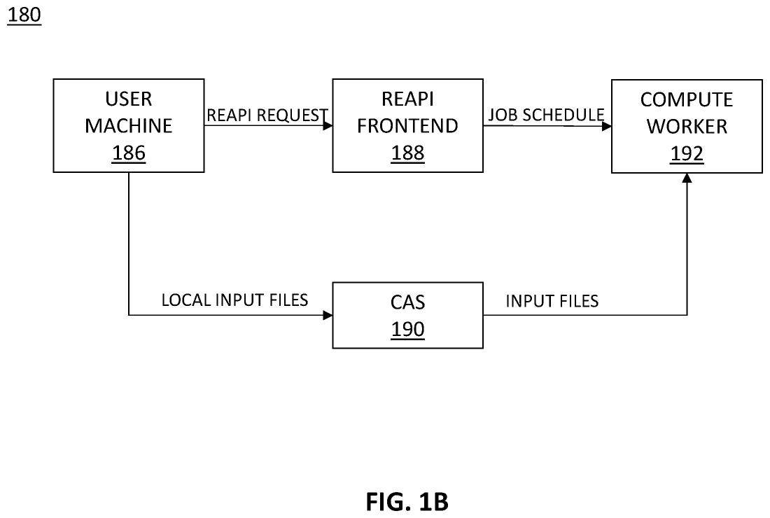

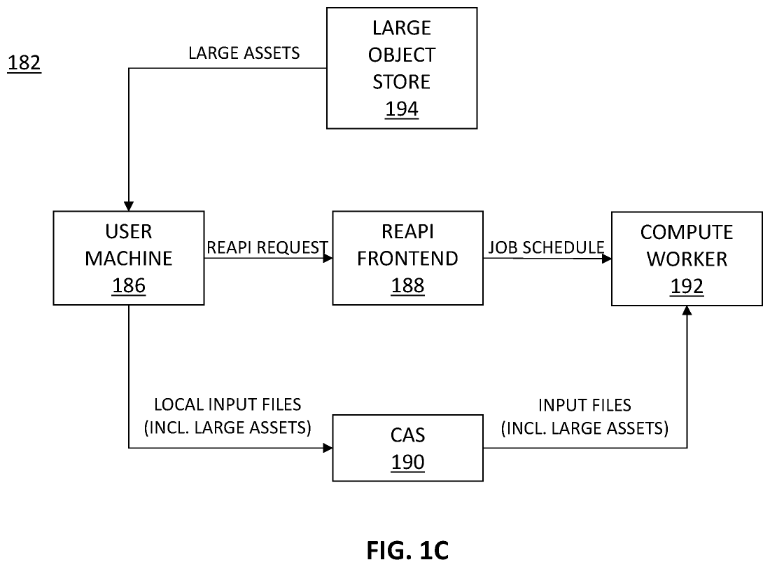

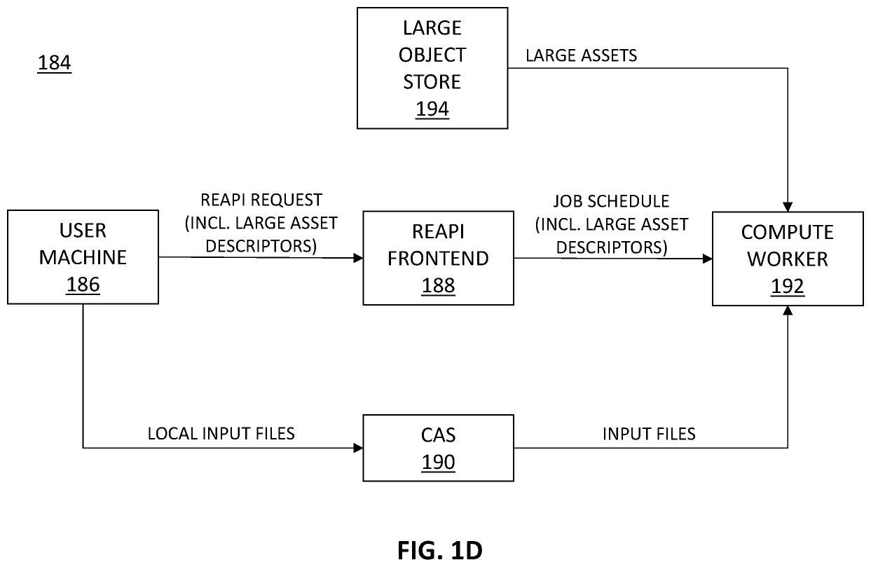

FIG. 1 illustrates an example of an AV management system 100. One of ordinary skill in the art will understand that, for the AV management system 100 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 100 includes an AV 102, a data center 150, and a client computing device 170, which in some embodiments may comprise an ADSC. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 102 can navigate roadways without a human driver based on sensor signals generated by multiple sensor systems 104, 106, and 108. The sensor systems 104-108 can include different types of sensors and can be arranged about the AV 102. For instance, the sensor systems 104-108 can comprise Inertial Measurement Units (IMUs), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other embodiments may include any other number and type of sensors.

AV 102 can also include several mechanical systems that can be used to maneuver or operate AV 102. For instance, the mechanical systems can include vehicle propulsion system 130, braking system 132, steering system 134, safety system 136, and cabin system 138, among other systems. Vehicle propulsion system 130 can include an electric motor, an internal combustion engine, or both. The braking system 132 can include an engine brake, a wheel braking system (e.g., a disc braking system that utilizes brake pads), hydraulics, actuators, and/or any other suitable componentry configured to assist in decelerating AV 102. The steering system 134 can include suitable componentry configured to control the direction of movement of the AV 102 during navigation. Safety system 136 can include lights and signal indicators, a parking brake, airbags, and so forth. The cabin system 138 can include cabin temperature control systems, in-cabin entertainment systems, and so forth. In some embodiments, the AV 102 may not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

AV 102 can additionally include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a planning stack 116, a control stack 118, a communications stack 120, a High Definition (HD) geospatial database 122, and an AV operational database 124, among other stacks and systems.

Perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 122, other components of the AV, and other data sources (e.g., the data center 150, the client computing device 170, third-party data sources, etc.). The perception stack 112 can detect and classify objects and determine their current and predicted locations, speeds, directions, and the like. In addition, the perception stack 112 can determine the free space around the AV 102 (e.g., to maintain a safe distance from other objects, change lanes, park the AV, etc.). The perception stack 112 can also identify environmental uncertainties, such as where to look for moving objects, flag areas that may be obscured or blocked from view, and so forth.

Mapping and localization stack 114 can determine the AV's position and orientation (pose) using different methods from multiple systems (e.g., GPS, IMUs, cameras, LIDAR, RADAR, ultrasonic sensors, the HD geospatial database 122, etc.). For example, in some embodiments, the AV 102 can compare sensor data captured in real-time by the sensor systems 104-108 to data in the HD geospatial database 122 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The planning stack 116 can determine how to maneuver or operate the AV 102 safely and efficiently in its environment. For example, the planning stack 116 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, DPVs, etc.), traffic rules and other safety standards or practices for the road, user input, and other relevant data for directing the AV 102 from one point to another. The planning stack 116 can determine multiple sets of one or more mechanical operations that the AV 102 can perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 116 can select from multiple backup plans to carry out. For example, while preparing to change lanes to turn right at an intersection, another vehicle may aggressively cut into the destination lane, making the lane change unsafe. The planning stack 116 could have already determined an alternative plan for such an event, and upon its occurrence, help to direct the AV 102 to go around the block instead of blocking a current lane while waiting for an opening to change lanes.

The control stack 118 can manage the operation of the vehicle propulsion system 130, the braking system 132, the steering system 134, the safety system 136, and the cabin system 138. The control stack 118 can receive sensor signals from the sensor systems 104-108 as well as communicate with other stacks or components of the local computing device 110 or a remote system (e.g., the data center 150) to effectuate operation of the AV 102. For example, the control stack 118 can implement the final path or actions from the multiple paths or actions provided by the planning stack 116. This can involve turning the routes and decisions from the planning stack 116 into commands for the actuators that control the AV's steering, throttle, brake, and drive unit.

The communication stack 120 can transmit and receive signals between the various stacks and other components of the AV 102 and between the AV 102, the data center 150, the client computing device 170, and other remote systems. The communication stack 120 can enable the local computing device 110 to exchange information remotely over a network, such as through an antenna array or interface that can provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 120 can also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 122 can store HD maps and related data of the streets upon which the AV 102 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane or road centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer can include geospatial information of traffic signal lights, traffic signs, and other road objects and related attributes.

The AV operational database 124 can store raw AV data generated by the sensor systems 104-108 and other components of the AV 102 and/or data received by the AV 102 from remote systems (e.g., the data center 150, the client computing device 170, etc.). In some embodiments, the raw AV data can include HD LIDAR point cloud data, image or video data, RADAR data, GPS data, and other sensor data that the data center 150 can use for creating or updating AV geospatial data.

The data center 150 can be a private cloud (e.g., an enterprise network, a co-location provider network, etc.), a public cloud (e.g., an laaS network, a PaaS network, a SaaS network, or other CSP network), a hybrid cloud, a multi-cloud, and so forth. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes one or more of a data management platform 152, an Artificial Intelligence/Machine Learning (AI/ML) platform 154, a simulation platform 156, a remote assistance platform 158, a ridesharing platform 160, and a map management platform 162, among other systems.

Data management platform 152 can be a “big data” system capable of receiving and transmitting data at high speeds (e.g., near real-time or real-time), processing a large variety of data, and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from the map management platform 162; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general purpose computing device for accessing the ridesharing application 172. The client computing device 170 can be a customer's mobile computing device or a computing device integrated with the AV 102 (e.g., the local computing device 110). The ridesharing platform 160 can receive requests to be picked up or dropped off from the ridesharing application 172 and dispatch the AV 102 for the trip.

Map management platform 162 can provide a set of tools for the manipulation and management of geographic and spatial (geospatial) and related attribute data. The data management platform 152 can receive LIDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as tracking specific changes that (human or machine) map editors have made to the data and reverting changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some embodiments, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the client application 172 to enable passengers to view the AV 102 in transit en route to a pick-up or drop-off location, and so on.

### Example Unified Simulation Interface System

In many software environments, there may be multiple disparate systems through which tasks, or jobs, (including, for example, simulations) are scheduled and executed using a backend compute cluster, which may execute tasks, produce results, and store results as data files for later consumption. Bazel remote execution application programming interface (REAPI) is an existing gRPC protocol that can be used to describe the foregoing operations. In accordance with features of embodiments described herein, simulations may be described as executables using Bazel REAPI extensions. In this manner, during a build process, users can also specify the additional data needed to use the same API to launch and run the simulation using the same Bazel client interface.

In accordance with features of embodiments described herein, native object fetching may be performed. In particular, a variety of specialized data stores may be provided for storing various types of data. Such data files may be quite large so it is advantageous not to move them more than absolutely necessary. To address this, a REAPI extension may be provided to describe a remote asset (e.g., a remote data file) as if it is local. The REAPI extension may include all of the information required to fetch the remote asset and move it directly to a compute worker, removing the need for the remote asset to be moved to intermediary machines. In particular embodiments, a native Bazel target may be defined and may specify and package all necessary metadata to schedule a replay onto a target backend, whether it is remote or local. The Bazel target is responsible for attaching any relevant metadata (such as map/bag addresses, test suite definitions, etc.) to the RBE request for successful execution. In particular embodiments, the Bazel target may use a series of user-defined configuration flags to expand the capabilities of the Bazel target (or a family of Bazel targets sharing logic).

FIGS. 1B-1D illustrate differences among an example standard REAPI operation 180 (FIG. 1B), an example standard REAPI operation with large assets 182 (FIG. 1C), and an example REAPI operation with native object fetching in accordance with features of embodiments described herein 184 (FIG. 1D).

Referring first to FIG. 1B, in example standard REAPI operation 180, a user machine 186 makes a REAPI request to a REAPI frontend 188 and provides local input files to content addressable storage (CAS) 190. REAPI frontend 188 and CAS 190 respectively provide a job schedule and input files to a compute worker 192.

Referring first to FIG. 1C, in example standard REAPI operation with large assets 182, a large object store 194 provides large assets to user machine 186. User machine 186 subsequently makes a REAPI request to REAPI frontend 188 and provides local input files, including the large assets, to CAS 190. REAPI frontend 188 and CAS 190 respectively provide a job schedule and input files including the large assets to compute worker 192.

Referring first to FIG. 1D, in example standard REAPI operation with large assets 184, user machine 186 makes a REAPI request to REAPI frontend 188 and provides local input files to CAS 190. REAPI frontend 188 and CAS 190 respectively provide a job schedule and input files including the large asset descriptors to compute worker 192. Additionally, large assets are provided directly to compute worker 192 from large asset store 194.

In additional embodiments, larger simulations may be described in batch (e.g., as a build graph) and may include branching logic. It is recognized that REAPI may be used to execute Bazel compilations, which are graphs of executions that must be run in order to achieve an output, with nodes representing executables and edges representing dependencies. In particular embodiments, a simulation may be described as a Bazel execution graph and may be sent through a REAPI in the same manner as described above. It will be recognized that Bazel only supports execution of static graphs, whereas simulations may include dynamic portions. In accordance with features of embodiments described therein, execution of a simulation execution graph may be divided into two phases (e.g., a static phase and a dynamic phase) in order to compute the entire graph using Bazel.

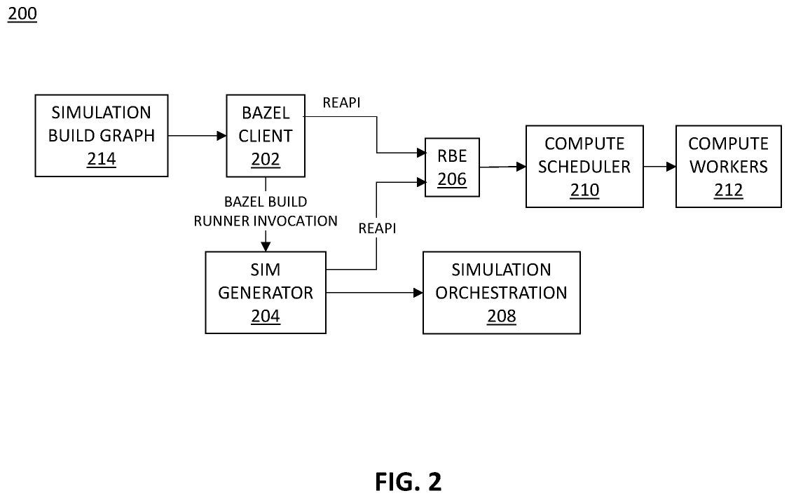

Referring now to FIG. 2, illustrated therein is a simplified block diagram of an example unified simulation interface (USI) system 200 in accordance with features of embodiments described herein. As shown in FIG. 2, system 200 includes a Bazel client 202 that interfaces with a sim generator 204 and a remote build execution service (RBE) 206 as will be described in greater detail hereinbelow. Sim generator 204 also interfaces directly with RBE 206 using REAPI as will be described as well as with a simulation orchestration layer 208. RBE 206 forwards jobs received from Bazel client 202 and sim generator 204 via REAPI payloads to compute scheduler 210, which schedules execution of the tasks on compute workers 212 until all of the tasks have been executed.

In particular embodiments, simulation orchestration layer 208 is an orchestration layer that watches and runs batch simulation jobs. Simulation orchestration layer 208 is aware of all the simulation details, including all of the input files and the simulation to be executed. In particular embodiments, the simulation orchestration layer 208 does not use an API protocol; therefore, sim generator 204 produces REAPI protocol requests to RBE service 206 to have them scheduled for execution by compute scheduler 210. In particular embodiments, sim generator 204 creates a payload that conforms to the REAPI, which compute scheduler 210 knows how to read. Compute scheduler 210 takes the jobs received from RBE service 206 and schedules them on compute workers 212.

In accordance with features of embodiments described herein, a simulation may be described as a Bazel execution graph 214 to be input to Bazel client 202. Graph 214 may include a static portion, which includes only static dependencies, and a dynamic portion, which includes dynamic dependencies. As will be described in greater detail below, there is a first static portion that is computed then a dynamic portion that is computed. More specifically, in accordance with features of embodiments described herein, the static pass will unwind the dynamic portion of the build graph, computing enough information that it can completely represent the dynamic portion of the build as a secondary static graph, then recursively invoke Bazel on the newly generated static representation. In alternative embodiments, this behavior may be recursed ad-infinitum to support arbitrarily interspersed dynamic graph portions.

Referring again to FIG. 2, Bazel client 202 processes the static portion of graph 214, forwarding REAPI payloads corresponding to execution nodes for processing to RBE service 206. When Bazel client 202 encounters a dynamic portion (or dynamic node) of graph 214, it uses a special invocation to invoke sim generator 204. As described in greater detail below, once invoked, sim generator 204 creates REAPI payloads for dynamic nodes of graph, which payloads are forwarded to RBE service 206. In particular embodiments, REAPI payloads may be created and written to disk using standard protocol buffer realization format. Serialized protocol buffers may be picked up by a client or other coordinating entry performing the launch and then put onto the wire. RBE service 206 does not distinguish between REAPI requests from Bazel client 202 or sim generator 204; it merely continues to schedule build test simulation targets to compute scheduler 210 in response to received REAPI payloads.

### Example Techniques for Implementing Aspects of a Unified Simulation Interface System

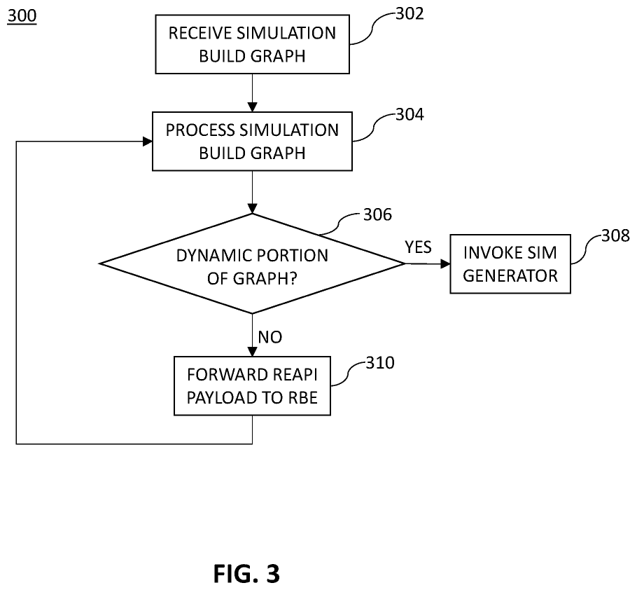

FIG. 3 is a flowchart 300 illustrating example operations that may be performed by components of a USI, such as USI 200, in accordance with particular embodiments. In certain embodiments, one or more of the operations illustrated in FIG. 3 may be executed by one or more of the elements shown in FIGS. 1, and/or 2, for example. In particular, operations shown in FIG. 3 may be implemented by Bazel client 202.

At 302, a simulation build graph is received by Bazel client. As previously noted, in many instances, a simulation build graph (such as simulation build graph 214) includes both a static portion comprising static build nodes and a dynamic portion comprising dynamic build nodes.

At 304, the received simulation build graph is processed. In particular, 304 results in a current node of simulation build graph being processed. At a first execution of 304, a first build node of simulation build graph is processed.

At 306, a determination is made whether a dynamic portion of the simulation build graph has been reached. For example, at 306, a determination may be made whether the current build node is a dynamic node, rather than a static node. If a positive determination is made at 306, execution proceeds to 308.

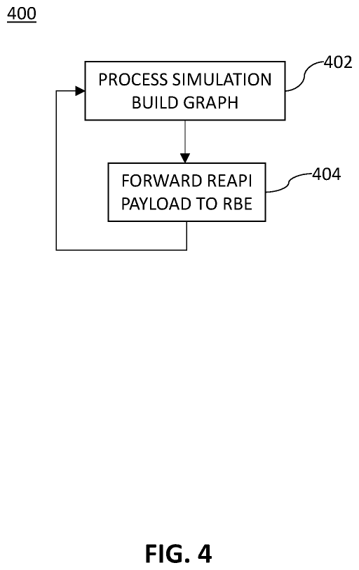

At 308, a sim generator (e.g., sim generator 204) is invoked. In particular embodiments, sim generator is invoked using a Bazel build runner invocation. Example operations performed in connection with sim generator will be described below with reference to FIG. 4. In particular embodiments, the static portion is fully processed before the dynamic portion, which runs to the end; however, in alternative embodiments, processing of the static and dynamic portions may be interspersed, allowing for arbitrary dynamic graph processing, including dynamic graph nesting (where a dynamic graph unrolls into another graph with additional dynamic components).

If at 306 a negative determination is made, execution proceeds to 310, at which an REAPI payload corresponding to the current node is forwarded to an RBE service, such as RBE service 206, to be scheduled by a compute scheduler, such as compute scheduler 210.

Execution then returns to 304 and the next node of the build graph is processed.

Although the operations of the example technique shown in and described with reference to FIG. 3 are illustrated as occurring once each and in a particular order, it will be recognized that the operations may be performed in any suitable order and repeated as desired. Additionally, one or more operations may be performed in parallel. Furthermore, the operations illustrated in FIG. 3 may be combined or may include more or fewer details than described.

FIG. 4 is a flowchart 400 illustrating example operations that may be performed by components of a USI, such as USI 200, in accordance with particular embodiments. In certain embodiments, one or more of the operations illustrated in FIG. 4 may be executed by one or more of the elements shown in FIGS. 1, and/or 2, for example. In particular, operations shown in FIG. 4 may be implemented by sim generator 204.

At 402, the simulation build graph is processed. In particular embodiments, a dynamic node of the simulation build graph received at 302 is processed to create an REAPI payload corresponding to the dynamic node. 402 may be accomplished using one of two methods. In a first method, the sim generator may write to disk a BUILD.bazel file that contains a Bazel CLI compliant input file representing the post-processed dynamic portion of the simulation build graph. The Bazel CLI tool may then be recursively invoked on the newly generated input file. In a second method, the sim generator may directly construct REAPI payloads either in-memory or on disk using the assistance of SDKs designed to support direct interaction with the REAPI. In this method, graph processing control essentially undergoes a handoff from the original Bazel process invocation to the sim generator process invocation.

At 404, the REAPI payload is forwarded to the RBE service for scheduling by the compute scheduler.

Although the operations of the example technique shown in and described with reference to FIG. 4 are illustrated as occurring once each and in a particular order, it will be recognized that the operations may be performed in any suitable order and repeated as desired. Additionally, one or more operations may be performed in parallel. Furthermore, the operations illustrated in FIG. 4 may be combined or may include more or fewer details than described.

### Example Processor-Based System

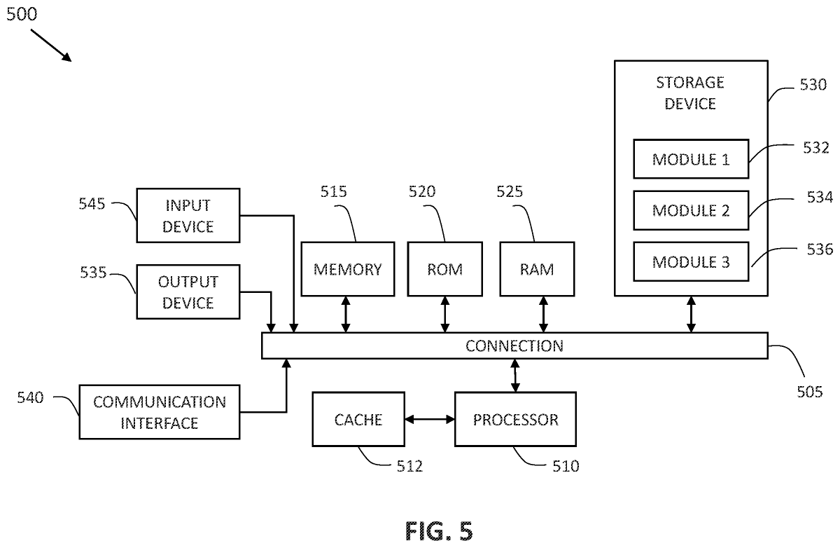

FIG. 5 illustrates an example processor-based system with which some aspects of the subject technology can be implemented. For example, processor-based system 500 can be any computing device making up, or any component thereof in which the components of the system are in communication with each other using connection 505. Connection 505 can be a physical connection via a bus, or a direct connection into processor 510, such as in a chipset architecture. Connection 505 can also be a virtual connection, networked connection, or logical connection.

In some embodiments, computing system 500 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 500 includes at least one processing unit (Central Processing Unit (CPU) or processor) 510 and connection 505 that couples various system components including system memory 515, such as Read-Only Memory (ROM) 520 and Random-Access Memory (RAM) 525 to processor 510. Computing system 500 can include a cache of high-speed memory 512 connected directly with, in close proximity to, or integrated as part of processor 510.

Processor 510 can include any general purpose processor and a hardware service or software service, such as services 532, 534, and 536 stored in storage device 530, configured to control processor 510 as well as a special purpose processor where software instructions are incorporated into the actual processor design. Processor 510 may essentially be a completely self-contained computing system, containing multiple cores or processors, a bus, memory controller, cache, etc. A multi-core processor may be symmetric or asymmetric.

To enable user interaction, computing system 500 includes an input device 545, which can represent any number of input mechanisms, such as a microphone for speech, a touch-sensitive screen for gesture or graphical input, keyboard, mouse, motion input, speech, etc. Computing system 500 can also include output device 535, which can be one or more of a number of output mechanisms known to those of skill in the art. In some instances, multimodal systems can enable a user to provide multiple types of input/output to communicate with computing system 500. Computing system 500 can include communications interface 540, which can generally govern and manage the user input and system output. The communication interface may perform or facilitate receipt and/or transmission wired or wireless communications via wired and/or wireless transceivers, including those making use of an audio jack/plug, a microphone jack/plug, a USB port/plug, an Apple® Lightning® port/plug, an Ethernet port/plug, a fiber optic port/plug, a proprietary wired port/plug, a Bluetooth® wireless signal transfer, a Bluetooth® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, WLAN signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 540 may also include one or more GNSS receivers or transceivers that are used to determine a location of the computing system 500 based on receipt of one or more signals from one or more satellites associated with one or more GNSS systems. GNSS systems include, but are not limited to, the US-based GPS, the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 530 can be a non-volatile and/or non-transitory and/or computer-readable memory device and can be a hard disk or other types of computer-readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid state memory, a Compact Disc Read-Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Static RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L #), Resistive RAM (RRAM/ReRAM), Phase Change Memory (PCM), Spin Transfer Torque RAM (STT-RAM), another memory chip or cartridge, and/or a combination thereof.

Storage device 530 can include software services, servers, services, etc., that when the code that defines such software is executed by the processor 510, it causes the system 500 to perform a function. In some embodiments, a hardware service that performs a particular function can include the software component stored in a computer-readable medium in connection with the necessary hardware components, such as processor 510, connection 505, output device 535, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network personal computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

### Selected Examples

Example 1 provides a unified simulation interface (USI) system including an interface module for receiving a simulation build graph, in which the simulation build graph includes a static portion and a dynamic portion, in which the interface module generates application programming interface (API) payloads for execution nodes including the static portion of the simulation build graph; a sim generator module for generating API payloads for execution nodes including the dynamic portion of the simulation build graph; and a remote build execution (RBE) service for receiving the API payloads generated by the interface module and the sim generator module, and scheduling execution of tasks in connection with the received API payloads on a compute cluster.

Example 2 provides the USI system of example 1, in which the sim generator is invoked by the interface module to process the execution nodes including the dynamic portion of the simulation build graph.

Example 3 provides the USI system of example 1 or 2, in which the interface module includes a Bazel client.

Example 4 provides the USI system of example 3, in which the API payloads include Bazel remote execution API (REAPI) payloads.

Example 5 provides the USI system of any one of examples 1-4, in which the compute cluster includes a compute scheduler and a plurality of compute workers.

Example 6 provides the USI system of any one of examples 1-5, in which the nodes including the dynamic portion of the simulation build graph include dynamic dependencies.

Example 7 provides the USI system of any one of examples 1-6, in which the nodes including the static portion of the simulation build graph include only static dependencies.

Example 8 provides the USI system of any one of examples 1-7, further including a native object fetching (NOF) service, in which the NOF service is configured to move a data asset described using a Bazel remote execution API (REAPI) extension directly to a compute worker from a data store remote from the compute worker.

Example 9 provides the USI system of example 8, in which the NOF service further includes a native Bazel target in which metadata for scheduling a replay on the compute worker is packaged.

Example 10 provides the USI system of example 9, in which the native Bazel target employs at least one user-defined configuration flag to expand capabilities of the native Bazel target.

Example 11 provides a computer-implemented method for implementing a unified simulation interface (USI), the computer-implemented method including receiving by a Bazel client a simulation build graph, in which the simulation build graph includes a static portion and a dynamic portion, in which the Bazel client generates application programming interface (API) payloads for execution nodes including the static portion of the simulation build graph; invoking by the Bazel client a sim generator module for generating API payloads for execution nodes including the dynamic portion of the simulation build graph; and scheduling by a remote build execution (RBE) service execution of tasks in connection with the received API payloads on a compute cluster.

Example 12 provides the computer-implemented method of example 11, in which the API payloads include Bazel remote execution API (REAPI) payloads.

Example 13 provides the computer-implemented method of example 11 or 12, in which the compute cluster includes a compute scheduler and a plurality of compute workers.

Example 14 provides the computer-implemented method of any one of examples 11-13, in which the nodes including the dynamic portion of the simulation build graph include dynamic dependencies and the nodes including the static portion of the simulation build graph include only static dependencies.

Example 15 provides the computer-implemented method of any one of examples 11-14, moving by a native object fetching (NOF) service a data asset described using a Bazel remote execution API (REAPI) extension directly to a compute worker from a data store remote from the compute worker.

Example 16 provides the computer-implemented method of example 15, in which the NOF service includes a native Bazel target in which metadata for scheduling a replay on the compute worker is packaged.

Example 17 provides one or more non-transitory computer-readable storage media including instructions for execution that, when executed by a processor, are operable to cause to be performed operations including receiving by a Bazel client a simulation build graph, in which the simulation build graph includes a static portion and a dynamic portion, in which the Bazel client generates application programming interface (API) payloads for execution nodes including the static portion of the simulation build graph; invoking by the Bazel client a sim generator module for generating API payloads for execution nodes including the dynamic portion of the simulation build graph; and scheduling by a remote build execution (RBE) service execution of tasks in connection with the received API payloads on a compute cluster.

Example 18 provides the one or more non-transitory computer-readable storage media of example 17, in which the API payloads include Bazel remote execution API (REAPI) payloads.

Example 19 provides the one or more non-transitory computer-readable storage media of example 17 or 18, in which the compute cluster includes a compute scheduler and a plurality of compute workers.

Example 20 provides the one or more non-transitory computer-readable storage media of any one of examples 17-19, in which the nodes including the dynamic portion of the simulation build graph include dynamic dependencies and the nodes including the static portion of the simulation build graph include only static dependencies.

### Other Implementation Notes, Variations, and Applications

It is to be understood that not necessarily all objects or advantages may be achieved in accordance with any particular embodiment described herein. Thus, for example, those skilled in the art will recognize that certain embodiments may be configured to operate in a manner that achieves or optimizes one advantage or group of advantages as taught herein without necessarily achieving other objects or advantages as may be taught or suggested herein.

In one example embodiment, any number of electrical circuits of the figures may be implemented on a board of an associated electronic device. The board can be a general circuit board that can hold various components of the interior electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), computer-readable non-transitory memory elements, etc. can be suitably coupled to the board based on particular configuration needs, processing demands, computer designs, etc. Other components such as exterior storage, additional sensors, controllers for audio/video display, and peripheral devices may be attached to the board as plug-in cards, via cables, or integrated into the board itself. In various embodiments, the functionalities described herein may be implemented in emulation form as software or firmware running within one or more configurable (e.g., programmable) elements arranged in a structure that supports these functions. The software or firmware providing the emulation may be provided on non-transitory computer-readable storage medium comprising instructions to allow a processor to carry out those functionalities.

It is also imperative to note that all of the specifications, dimensions, and relationships outlined herein (e.g., the number of processors, logic operations, etc.) have only been offered for purposes of example and teaching only. Such information may be varied considerably without departing from the spirit of the present disclosure, or the scope of the appended examples. The specifications apply only to one non-limiting example and, accordingly, they should be construed as such. In the foregoing description, example embodiments have been described with reference to particular arrangements of components. Various modifications and changes may be made to such embodiments without departing from the scope of the appended examples. The description and drawings are, accordingly, to be regarded in an illustrative rather than in a restrictive sense.

Note that with the numerous examples provided herein, interaction may be described in terms of two, three, four, or more components; however, this has been done for purposes of clarity and example only. It should be appreciated that the system can be consolidated in any suitable manner. Along similar design alternatives, any of the illustrated components, modules, and elements of the FIGS. may be combined in various possible configurations, all of which are clearly within the broad scope of this Specification.

Various operations may be described as multiple discrete actions or operations in turn in a manner that is most helpful in understanding the example subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Note that in this Specification, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments.

Numerous other changes, substitutions, variations, alterations, and modifications may be ascertained to one skilled in the art and it is intended that the present disclosure encompass all such changes, substitutions, variations, alterations, and modifications as falling within the scope of the appended examples. Note that all optional features of the systems and methods described above may also be implemented with respect to the methods or systems described herein and specifics in the examples may be used anywhere in one or more embodiments.

In order to assist the United States Patent and Trademark Office (USPTO) and, additionally, any readers of any patent issued on this application in interpreting the examples appended hereto, Applicant wishes to note that the Applicant: (a) does not intend any of the appended examples to invoke paragraph (f) of 35 U.S.C. Section 112 as it exists on the date of the filing hereof unless the words “means for” or “step for” are specifically used in the particular examples; and (b) does not intend, by any statement in the Specification, to limit this disclosure in any way that is not otherwise reflected in the appended examples.

What is claimed is:

1. A unified simulation interface system comprising:
an interface module for receiving a simulation build graph, wherein the simulation build graph comprises a static portion and a dynamic portion, and the interface module generates application programming interface (API) payloads for execution nodes comprising the static portion of the simulation build graph;
a simulation generator module for generating API payloads for execution nodes comprising the dynamic portion of the simulation build graph; and
a remote build execution service for receiving the API payloads generated by the interface module and the simulation generator module, and scheduling execution of tasks in connection with the received API payloads for the execution nodes of the simulation build graph on a compute cluster.

2. The unified simulation interface system of claim 1, wherein the simulation generator is invoked by the interface module to process the execution nodes comprising the dynamic portion of the simulation build graph.

3. The unified simulation interface system of claim 1, wherein the interface module comprises a Bazel client.

4. The unified simulation interface system of claim 3, wherein the API payloads comprise Bazel remote execution API (REAPI) payloads.

5. The unified simulation interface system of claim 1, wherein the compute cluster comprises a compute scheduler and a plurality of compute workers.

6. The unified simulation interface system of claim 1, wherein the nodes comprising the dynamic portion of the simulation build graph comprise dynamic dependencies among the nodes of the dynamic portion of the simulation build graph.

7. The unified simulation interface system of claim 1, wherein the nodes comprising the static portion of the simulation build graph comprise only static dependencies.

8. The unified simulation interface system of claim 1, further comprising a native object fetching service, wherein the native object fetching service is configured to move a data asset described using a Bazel remote execution API (REAPI) extension directly to a compute worker from a data store remote from the compute worker.

9. The unified simulation interface system of claim 8, wherein the native object fetching service further comprises a native Bazel target in which metadata for scheduling a replay on the compute worker is packaged.

10. The unified simulation interface system of claim 9, wherein the native Bazel target employs at least one user-defined configuration flag to expand capabilities of the native Bazel target.

11. A computer-implemented method for implementing a unified simulation interface, the computer-implemented method comprising:
receiving, by a software client, a simulation build graph, wherein the simulation build graph comprises a static portion and a dynamic portion, and the software client generates application programming interface (API) payloads for execution nodes comprising the static portion of the simulation build graph;
invoking, by the software client, a simulation generator module for generating API payloads for execution nodes comprising the dynamic portion of the simulation build graph; and
scheduling, by a remote build execution service, execution of tasks in connection with the received API payloads on a compute cluster.

12. The computer-implemented method of claim 11, wherein the API payloads comprise Bazel remote execution API (REAPI) payloads.

13. The computer-implemented method of claim 11, wherein the compute cluster comprises a compute scheduler and a plurality of compute workers.

14. The computer-implemented method of claim 11, wherein the nodes comprising the dynamic portion of the simulation build graph comprise dynamic dependencies and the nodes comprising the static portion of the simulation build graph comprise only static dependencies.

15. The computer-implemented method of claim 11, further comprising moving by a native object fetching service a data asset described using a Bazel remote execution API (REAPI) extension directly to a compute worker from a data store remote from the compute worker.

16. The computer-implemented method of claim 15, wherein the native object fetching service includes a native Bazel target in which metadata for scheduling a replay on the compute worker is packaged.

17. One or more non-transitory computer-readable storage media comprising instructions for execution that, when executed by a processor, are operable to cause to be performed operations comprising:
receiving by a software client a simulation build graph, wherein the simulation build graph comprises a static portion and a dynamic portion, and the software client generates application programming interface (API) payloads for execution nodes comprising the static portion of the simulation build graph;
invoking by the software client a simulation generator module for generating API payloads for execution nodes comprising the dynamic portion of the simulation build graph; and
scheduling by a remote build execution service execution of tasks in connection with the received API payloads on a compute cluster.

18. The one or more non-transitory computer-readable storage media of claim 17, wherein the API payloads comprise Bazel remote execution API (REAPI) payloads.

19. The one or more non-transitory computer-readable storage media of claim 17, wherein the compute cluster comprises a compute scheduler and a plurality of compute workers.

20. The one or more non-transitory computer-readable storage media of claim 17, wherein the nodes comprising the dynamic portion of the simulation build graph comprise dynamic dependencies and the nodes comprising the static portion of the simulation build graph comprise only static dependencies.
